(19) United States
(12) Patent Application Publication
(10) Pub. No.: US 2005/0083071 A1
(43) Pub. Date: Apr. 21, 2005

(54) Electronic circuit assembly test apparatus

(76) Inventors: Fred Hartnett, Plano, TX (US); Kin Tam, Elk Grove, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/686,699

(22) Filed: Oct. 16, 2003

(51) Int. Cl. G01R 31/02

(52) U.S. Cl. 324/754

(57) ABSTRACT

An electronic circuit assembly test apparatus comprises a support member having a plurality of probes each adapted to contact a corresponding test area of an electronic circuit assembly. The apparatus also comprises a probe assembly coupled to the support member. The probe assembly also comprises a plurality of probes where a spacing density of the probes of the probe assembly is greater than a spacing density of the probes of the support member.

### TECHNICAL FIELD OF THE INVENTION

The present invention relates generally to the field of electronics testing equipment and, more particularly, to an electronic circuit assembly test apparatus.

### BACKGROUND OF THE INVENTION

Contact-based test probes are generally used to perform analog and digital testing in both powered and un-powered states of printed circuit boards, multi-chip modules, and/or other types of electronic circuit assemblies. For example, the test probes are generally mounted to a flat test fixture at locations corresponding to test areas or pads of a printed circuit board. The test probes are generally spring-loaded and contact the test areas of the printed circuit board as the test fixture is moved toward the printed circuit board. The probes are connected to test equipment to drive and sense voltages and/or currents for performing testing procedures on the printed circuit board.

As the designs of electronic circuit assemblies and electronic components advance, in-circuit testing of electronic circuits has become increasingly difficult. For example, because of test probe pitch distance limitations, integrated circuit packages and other components and/or locations of electronic circuits having high density or low pitch pin distance or test area dimensions cannot be readily tested. For these high density testing areas, testing must be performed at other locations on the network. Alternatively, additional test pads may be provided on the electronic circuit. However, the additional test pads increase the complexity of the electronic circuit design by utilizing space otherwise used for high density electrical routing.

### SUMMARY OF THE INVENTION

In accordance with one embodiment of the present invention, an electronic circuit assembly test apparatus comprises a support member having a plurality of probes each adapted to contact a corresponding test area of an electronic circuit assembly. The test apparatus also comprises a probe assembly coupled to the support member. The probe assembly also comprises a plurality of probes where a spacing density of the probes of the probe assembly is greater than a spacing density of the probes of the support member.

In accordance with another embodiment of the present invention, an electronic circuit assembly test apparatus comprises a plurality of probes coupled to a support member. The probes are adapted to contact corresponding test areas of an electronic circuit assembly. The test apparatus also comprises a probe assembly movably coupled to the support member. The probe assembly also comprises a plurality of probes adapted to contact corresponding test areas of the electronic circuit assembly.

In accordance with yet another embodiment of the present invention, an electronic circuit assembly test apparatus comprises a support member, a test probe assembly having a plurality of probes adapted to contact corresponding test areas of a printed circuit board assembly, and a float assembly disposed between the test probe assembly and the support member.

### BRIEF DESCRIPTION OF THE DRAWINGS

For a more complete understanding of the present invention and the advantages thereof, reference is now made to the following descriptions taken in connection with the accompanying drawings in which:

FIG. 1 is a diagram illustrating an embodiment of an electronic circuit assembly test apparatus in accordance with the present invention;

FIGS. 2A and 2B are diagrams illustrating an embodiment of corresponding portions of the electronic circuit assembly test apparatus and electronic circuit assembly illustrated in FIG. 1;

FIG. 3 is a diagram illustrating another embodiment of an electronic circuit assembly test apparatus in accordance with the present invention; and

FIG. 4 is a top view of the embodiment of the electronic circuit assembly test apparatus illustrated in FIG. 3.

### DETAILED DESCRIPTION OF THE DRAWINGS

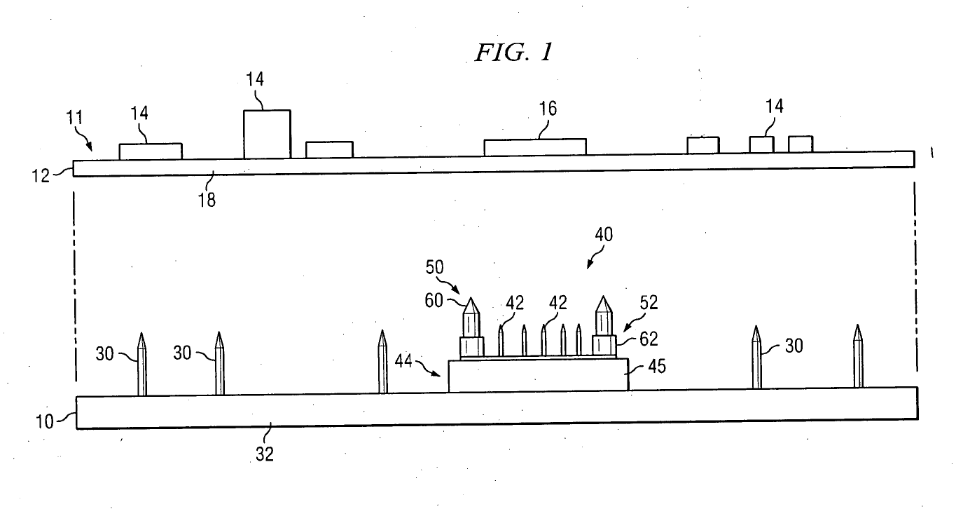

The preferred embodiments of the present invention and the advantages thereof are best understood by referring to FIGS. 1-4 of the drawings, like numerals being used for like and corresponding parts of the various drawings.

FIG. 1 is a diagram illustrating an embodiment of an electronic circuit assembly test apparatus 10 in accordance with the present invention. Briefly, apparatus 10 enables in-circuit testing of printed circuit board assemblies, multi-chip modules, and/or other types of electronic circuit assemblies having high density electrical routing patterns and/or high density test pad locations corresponding to, for example, high density integrated circuit packages. In accordance with one embodiment of the present invention, apparatus 10 comprises a set of small diameter test probes arranged in a desired density or spacing arrangement to accommodate corresponding test pad or integrated circuit pin locations. The small diameter test probes are located on a floating or movable assembly to improve probe placement accuracy relative to an electronic circuit assembly, thereby enabling smaller test pads to be located on the electronic circuit assembly and to compensate for the effects of electronic circuit assembly process and planarity variations. Thus, embodiments of the present invention enable precise or local registration of test probes with corresponding high density test pads or contact areas of an electronic circuit assembly.

In FIG. 1, apparatus 10 is illustrated adjacent an electronic circuit assembly 11 to enable testing, such as in-circuit testing, of electronic circuit assembly 11. In FIGS. 1-4, electronic circuit assembly 11 is illustrated as a printed circuit board assembly 12; however, it should be understood that electronic circuit assembly 11 may comprise other types of electronic circuit devices such as, but not limited to, multi-chip modules. Printed circuit board assembly 12 may comprise a variety of types of electronic components 14 such as, but not limited to, capacitors, resistors, and one or more integrated circuits 16 attached to a printed circuit board 18. Printed circuit board 18 may comprise a single-layer board or a multiple-layer board having associated electrical trace routing.

In the embodiment illustrated in FIG. 1, apparatus 10 comprises at least one test probe 30 coupled to a test fixture support member 32. Apparatus 10 also comprises a probe assembly 40 coupled to support member 32. Probe assembly 40 comprises test probes 42 for contacting corresponding test pads or other types of test areas of printed circuit board assembly 12. For example, in the embodiment illustrated in FIG. 1, test probes 42 are disposed in general alignment with integrated circuit 16 to accommodate contact with pins or associated test pads relating to circuit 16. However, it should be understood that probe assembly 40 may be used to perform testing operations at any location of printed circuit board assembly 12.

In the embodiment illustrated in FIG. 1, test probes 30 and 42 comprise spring-loaded or spring-biased probes for contacting corresponding areas or pads of printed circuit board assembly 12. However, it should be understood that other types of probes or contacting devices may be used to access test areas of printed circuit board assembly 12. Test probes 42 of probe assembly 40 are generally sized smaller than test probes 30 to accommodate a greater probe density spacing arrangement on probe assembly 40. For example, test probes 42 are generally of a smaller diameter than test probes 30 to enable a tighter pitch or closer spacing arrangement of test probes 42 corresponding to high density test areas of printed circuit board assembly 12. Additionally, because of a decreased diameter of test probes 42, a length of test probes 42 may also be sized smaller than a length of test probes 30 to reduce the likelihood of damage to test probes 42 from sheer stresses generated by contact of test probes 42 with printed circuit board assembly 12. As illustrated in FIG. 1, probe assembly 40 also comprises a probe assembly support 44 to locate distal ends of test probes 42 at locations to enable contact with corresponding test areas of printed circuit board assembly 12 and correspond to distal locations of test probes 30. For example, in the embodiment illustrated in FIG. 1, probe assembly support 44 comprises at least one support member 45 coupled to test fixture support member 32 and having a thickness to accommodate a desired distal placement of probes 42.

As illustrated in FIG. 1, probe assembly 40 also comprises an alignment guide 50 and a limiter 52. Alignment guide 50 is adapted to provide precise or fine alignment of test probes 42 with corresponding test areas of printed circuit board assembly 12 prior to contact of test probes 42 with printed circuit board assembly 12, thereby reducing or practically eliminating sheer stresses applied to test probes 42 as test probes 42 contact printed circuit board assembly 12. In the embodiment illustrated in FIG. 1, alignment guide 50 comprises at least one alignment pin 60 adapted to cooperate with a corresponding hole or opening formed in printed circuit board assembly 12. However, it should be understood that other types of alignment mechanisms may be used to provide fine alignment of test probes 42 with printed circuit board assembly 12. For example, in operation, as apparatus 10 is directed toward printed circuit board assembly 12, alignment pin 60 cooperates with an opening or hole formed in printed circuit board assembly 12 to align probes 42 of probe assembly 40 with corresponding test areas of printed circuit board assembly 12.

Limiter 52 provides travel distance control of test probes 42 relative to printed circuit board assembly 12 to substantially prevent or eliminate overextension or overcompression of test probes 42 resulting from contact with printed circuit board assembly 12. For example, in the embodiment illustrated in FIG. 1, limiter 52 comprises at least one stop 62 to limit travel of probe assembly 40 and, correspondingly, test probes 42 toward printed circuit board assembly 12. In FIG. 1, stop 62 is formed as an integral part of alignment guide 50 such that, in operation, a diameter of stop 62 is formed greater than a diameter of alignment pin 60 to enable passage of alignment pin 60 through a correspondingly sized opening formed in printed circuit board assembly 12 while preventing passage of stop 62 through the corresponding opening formed in printed circuit board assembly 12. However, it should be understood that other types of devices or methods may be used to prevent overextension or overcompression of test probes 42 resulting from contact of test probes 42 with printed circuit board assembly 12. Additionally, limiter 52 may also be formed or constructed as a separate and discrete component apart from alignment guide 50.

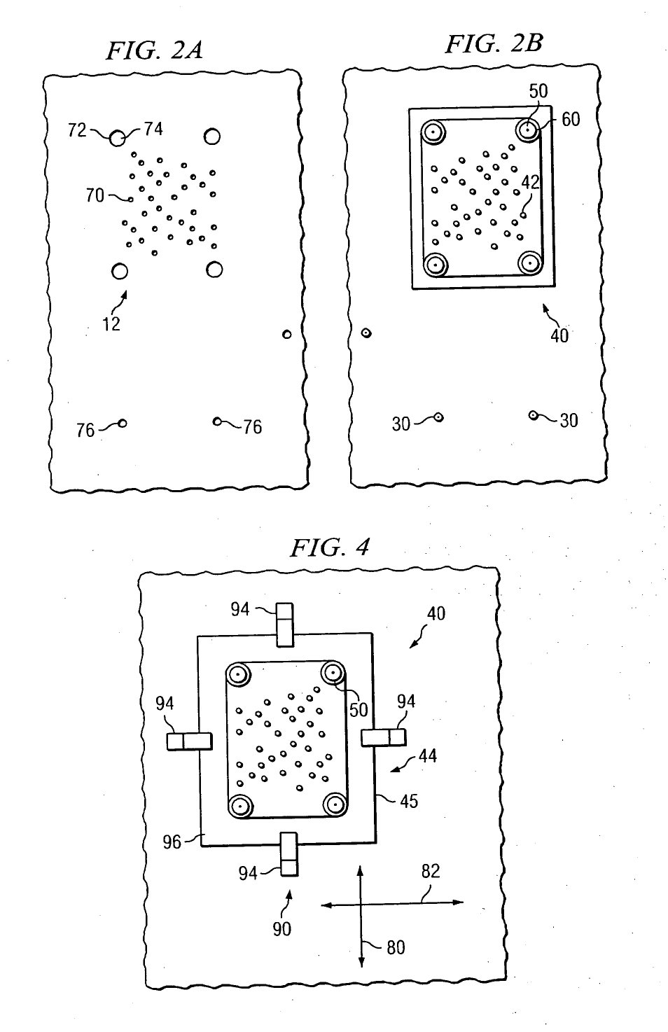

FIGS. 2A and 2B are diagrams illustrating corresponding portions of printed circuit board assembly 12 and probe assembly 40 in accordance with an embodiment of the present invention, respectively. As illustrated in FIG. 2A, printed circuit board assembly 12 comprises test pads or areas 70 for receiving test probes 42 of probe assembly 40. Additionally, printed circuit board assembly 12 comprises an alignment guide 72 adapted to cooperate with alignment guide 50 of probe assembly 40. For example, in the embodiment illustrated in FIG. 2A, alignment guide 72 comprises a hole or opening 74 for receiving alignment pin 60 of probe assembly 40. Printed circuit board assembly 12 also comprises test pads or areas 76 for receiving and/or cooperating with test probes 30. As illustrated in FIGS. 2A and 2B, a spacing density of probes 42 is greater than a spacing density of probes 30, thereby enabling in-circuit testing of high density test areas or routing patterns of printed circuit board assembly 12.

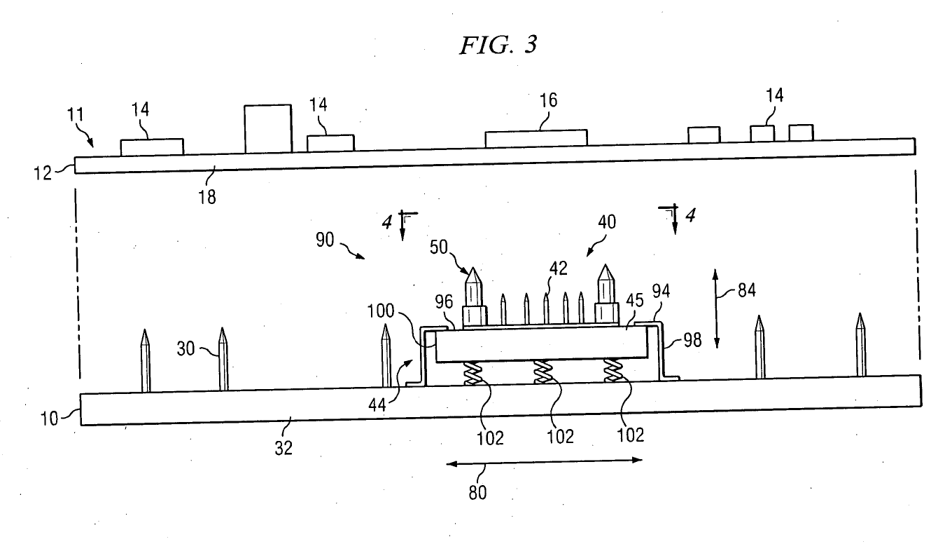

FIG. 3 is a diagram illustrating another embodiment of electronic circuit assembly test apparatus 10 in accordance with the present invention, and FIG. 4 is a top view of the embodiment illustrated in FIG. 3 in accordance with the present invention. As illustrated in FIGS. 3 and 4, probe assembly support 44 is configured to movably couple probe assembly 40 to support member 32 to accommodate lateral movement in the directions indicated generally at 80 and 82 relative to support member 32 and non-laterally indicated in the direction generally at 84. For example, in the embodiment illustrated in FIGS. 3 and 4, probe assembly support 44 comprises a float assembly 90 for providing both lateral and non-lateral movement of probe assembly 40 relative to support member 32. In FIGS. 3 and 4, float assembly 90 comprises clips 94 coupled to support member 32 and extending to an upper surface 96 of support member 45. Vertical portions 98 of clips 94 are disposed spaced apart from edges 100 of support member 45 to accommodate lateral movement of probe assembly 40 in directions 80 and 82. Thus, in operation, as apparatus 10 is moved toward printed circuit board assembly 12, each alignment guide 50 cooperates with a corresponding alignment guide 72 of printed circuit board assembly 12 to align probe assembly 40 with corresponding test areas 70 of printed circuit board assembly 12. For example, as alignment pins 60 enter corresponding openings 74 of printed circuit board assembly 12, float assembly 90 enables lateral movement of probe assembly 40 to provide precise or fine alignment of test probes 42 with corresponding test areas 70 of printed circuit board assembly 12. However, it should be understood that other devices or mechanisms may be used to movably couple probe assembly 40 to support member 32 to provide lateral movement of probe assembly 40 relative to support member 32.

In the embodiment illustrated in FIG. 3, float assembly 90 also comprises at least one spring 102 disposed between support member 45 and support member 32 to bias probe assembly 40 toward printed circuit board assembly 12 in the direction indicated generally at 84. In the embodiment illustrated in FIGS. 3 and 4, springs 102 cooperate with clips 94 to provide lateral and non-lateral movement of probe assembly 40 and enables alignment of probe assembly 40 in the direction indicated generally at 84 to accommodate planarity variations and circuit board assembly 12 dimensional variations. For example, although the distal ends of probes 30 and/or 42 may be sized and/or correlated to a particular feature or area of printed circuit board assembly 12, planar variations in printed circuit board 18 and/or variations of sizes of components 14 may cause varied or improper contact of probes 30 and/or 42 with corresponding test areas of printed circuit board assembly 12. Float assembly 90 enables non-lateral movement of probe assembly 40 relative to support member 21 and, correspondingly, printed circuit board assembly 12, to accommodate planarity variations and/or various component 14 sizes of printed circuit board assembly 12 while reducing or substantially eliminating the likelihood of improper contact or seating of probes 30 and/or 42 with test areas of printed circuit board assembly 12. However, it should be understood that other devices or mechanisms may be used to provide non-lateral movement of probe assembly 40 relative to support member 32.

Thus, embodiments of the present invention enable in-circuit and other types of electronic circuit testing while accommodating high density test pad spacing and/or high density component pin spacing. Embodiments of the present invention also provide for enhanced alignment or local registration of densely spaced test probes with corresponding test areas of an electronic circuit assembly by enabling floating movement of a densely spaced test probe assembly in lateral and/or non-lateral directions relative to an electronic circuit assembly.

1. An electronic circuit assembly test apparatus, comprising:
a support member having a plurality of probes, each probe adapted to contact a corresponding test area of an electronic circuit assembly; and
a probe assembly coupled to the support member, the probe assembly having a plurality of probes, wherein a spacing density of the probes of the probe assembly is greater than a spacing density of the probes of the support member.

2. The apparatus of claim 1, wherein the spacing density of the probes of the probe assembly corresponds to test areas of an integrated circuit.

3. The apparatus of claim 1, wherein the probe assembly is adapted to move laterally relative to the support member.

4. The apparatus of claim 1, wherein the probe assembly comprises at least one alignment guide adapted to cooperate with an alignment guide disposed on the electronic circuit assembly.

5. The apparatus of claim 1, wherein the probe assembly comprises at least one limiter adapted to limit movement of the probes of the probe assembly toward the electronic circuit assembly.

6. The apparatus of claim 1, wherein the probe assembly is movably coupled to the support member to provide non-lateral movement of the probe assembly relative to the support member.

7. The apparatus of claim 1, wherein the probes of the probe assembly comprise spring-biased probes.

8. The apparatus of claim 1, further comprising at least one spring disposed between the probe assembly and the support member.

9. An electronic circuit assembly test apparatus, comprising:
first probe means coupled to a support member and adapted to contact corresponding test areas on an electronic circuit assembly;
support means coupled to the support member; and
second probe means coupled to the support means, the second probe means having a spacing density of probes greater than a spacing density of probes of the first probe means.

10. The apparatus of claim 9, wherein the support means is movably coupled to the support member.

11. The apparatus of claim 9, wherein the support means is coupled to the support member to enable lateral movement of the support means relative to the support member.

12. The apparatus of claim 9, further comprising means for aligning the second probe means with corresponding test areas of the electronic circuit assembly.

13. The apparatus of claim 9, further comprising means for limiting travel of the second probe means toward the electronic circuit assembly.

14. An electronic circuit assembly test apparatus, comprising:
a plurality of probes coupled to a support member, the probes adapted to contact corresponding test areas of an electronic circuit assembly; and
a probe assembly movably coupled to the support member, the probe assembly comprising a plurality of probes adapted to contact corresponding test areas of the electronic circuit assembly.

15. The apparatus of claim 14, wherein the probe assembly is movably coupled to the support member to enable lateral movement of the probe assembly relative to the support member.

16. The apparatus of claim 14, wherein the probe assembly is movably coupled to the support member to enable non-lateral movement of the probe assembly relative to the support member.

17. The apparatus of claim 14, wherein the probe assembly comprises at least one limiter adapted to limit travel of the probes of the probe assembly toward the electronic circuit assembly.

18. The apparatus of claim 14, wherein the probe assembly comprises at least one alignment guide adapted to align the probes of the probe assembly with corresponding test areas of the electronic circuit assembly.

19. An electronic circuit assembly test apparatus, comprising:
a support member;
a test probe assembly having a plurality of probes adapted to contact corresponding test areas of an electronic circuit assembly; and
a float assembly disposed between the test probe assembly and the support member.

20. The apparatus of claim 19, wherein the float assembly is adapted to bias the test probe assembly away from the support member.

21. The apparatus of claim 19, wherein the float assembly is adapted to enable lateral movement of the test probe assembly relative to the support member.

22. The apparatus of claim 19, wherein the float assembly is adapted to enable non-lateral movement of the test probe assembly relative to the support member.

23. The apparatus of claim 19, further comprising at least one limiter adapted to limit movement of the probes of the test probe assembly toward the electronic circuit assembly.

24. The apparatus of claim 19, further comprising at least one alignment guide adapted to align the probes with the corresponding test areas of the electronic circuit assembly.

25. The apparatus of claim 19, wherein the test probe assembly comprises at least one alignment pin adapted to cooperate with the electronic circuit assembly to align the probes with the test areas of the electronic circuit assembly.

26. The apparatus of claim 19, wherein the test probe assembly comprises at least one stop adapted to limit movement of the probe assembly toward the electronic circuit assembly.

27. The apparatus of claim 19, wherein the float assembly comprises at least one spring disposed between the test probe assembly and the support member.
